(19) United States
(12) Patent Application Publication
(10) Pub. No.: US 2016/0133696 A1
(43) Pub. Date: May 12, 2016

(54) FIN-FET STRUCTURE AND METHOD OF MANUFACTURING SAME

(71) Applicant: INSTITUTE OF MICROELECTRONICS, CHINESE ACADEMY OF SCIENCES, Beijing (CN)

(72) Inventors: Haizhou Yin, Poughkeepsie, NY (US); Keke Zhang, Liaocheng City, Shandong (CN)

(73) Assignee: Institute of Microlectronics, Chinese Academy of Sciences, Beijing (CN)

(21) Appl. No.: 14/900,491

(22) PCT Filed: Oct. 21, 2013
(86) PCT No.: PCT/CN2013/085553

§ 371 Date: Dec. 21, 2015

(30) Foreign Application Priority Data
Oct. 14, 2013 (CN) 201310478631.X

(51) Int. Cl. H01L 29/06; H01L 29/10; H01L 29/78; H01L 29/66

(52) U.S. Cl. CPC H01L 29/0638; H01L 29/66537; H01L 29/66795; H01L 29/0653; H01L 29/1037; H01L 29/7851

(57) ABSTRACT

A method for fabricating a FinFET DEVICE is provided in the invention, comprising: a. providing a substrate (100);b. forming a fin (200) on the substrate (200); c. depositing a doping material layer (300) on the semiconductor structure formed after the step b; d. forming a first shallow trench isolation (400) on the semiconductor formed after the step c; e. removing a portion of the doping material layer (300) which is not covered by the first shallow trench isolation (400); f. performing an annealing process to form a doped region (500) in a channel region which is in the middle portion of the fin; g. forming a second shallow trench isolation (600) on the semiconductor formed after the step f; h. forming a source region and a drain region in opposite portions of the fin and forming a gate stack on the middle portion of the fin. Comparing with the prior art, punch through effect will be restrained and process complexity will be reduced.

This application claims priority to Chinese Application No. 201310478631.X, filed on, Oct. 14, 2013, entitled “FIN-FET STRUCTURE AND METHOD OF MANUFACTURING SAME,” which is incorporated herein by reference in its entirety.

### TECHNICAL FIELD

The present disclosure generally relates to a semiconductor device and a method of fabricating the same, and in particular, to a FinFET device and a method of fabricating the same.

### BACKGROUND

With dimensional scaling of semiconductor device, threshold voltage decreases with the reduction of channel length, i.e. short channel effects arise in semiconductor device. Fin Field Effect Transistor, FinFET is developed to face the challenge from semiconductor design and manufacture.

Channel punch-through effect is a phenomenon that, the depletion regions of source junction and drain junction punch through in a Field Effect Transistor. When channel is punched through, the potential barrier between source and drain will decrease severely, such that a large number of carriers from source will be injected into channel and drift through the space-charge region between source and drain. As a result, there is forming a heavy current which is called space-charge-limited current for it is limited by space-charge. Due to the channel punch through, the the total current in device will greatly increase for space-charge-limited current will join the channel current which is controlled by gate; and there will be always a current between source and drain even when the gate voltage is lower than threshold voltage. The phenomenon is possibly occurred in small dimension device and the impact that is imposed on device will become serious with the reduction of channel thickness.

In FinFET manufacturing, punch through effect always can be restrained by a heavily doped region in a portion of the fin just under the channel region. In the prior art, a normal doping method is performed by ion implantation to form the heavily doped region, however, it is hard to accurately control the ion implantation depth and avoid damages to the channel surface. Normally, a thin oxide film may be formed on the channel surface to eliminate the damages, however, which may increase process complexity.

To resolve the forgoing problems, there is provided a novel channel doping method for FinFET manufacturing, comprising: a layer of borosilicate glass or phosphorosilicate glass is deposited after a fin formed on a substrate, then the dopants in the borosilicate glass or phosphorosilicate glass may diffuse into the channel region by anneal so as to form the expected heavily doped region. Comparing with the prior art, the punch through effect will be restrained and the complexity of process will be reduced at the same time by the present invention.

### SUMMARY OF THE INVENTION

There is provided a FinFET fabricating method in the present invention, the channel punch through effect can be restrained and process complexity can be reduced through the present invention. Specifically, the FinFET fabricating method comprises: a. providing a substrate; b. forming a fin on the substrate; c. depositing a doping material layer on the semiconductor structure formed after the step b; d. forming a first shallow trench isolation on the semiconductor structure formed after the step c; e. removing a portion of the doping material layer which is not covered by the first shallow trench isolation; f. performing an anneal process to form a doped region in a channel region which is in the middle portion of the fin; g. forming a second shallow trench isolation on the semiconductor structure formed after the step f; h. forming a source region and a drain region in both ends of the fin and forming a gate stack on the middle portion of the fin.

In one aspect of the present invention, the distance from the top surface of the first shallow trench isolation to the top surface of the fin is 20˜60 nm, the thickness of the second shallow trench isolation is equal to or larger than half of the channel thickness.

In one aspect of the present invention, the doping material layer comprises borosilicate glass or phosphorosilicate glass, wherein, the doping material layer comprises borosilicate glass for an N-type device while phosphorosilicate glass for a P-type device.

In one aspect of the present invention, the maximum doping concentration of the doped region is 1e18 cm⁻³˜1e19 cm⁻³.

Accordingly, there is provided a FinFET device, comprises: a substrate; a fin on the substrate; a gate stack covering the middle portion of the fin; a first shallow trench isolation on the substrate and on both sides of the fin, wherein, the top of the first shallow trench isolation is lower than the top of the fin; a doping material layer, wherein, in a horizontal direction, the doping material layer is between the first shallow trench isolation and the substrate, while in a vertical direction, the doping material layer is between the first shallow trench isolation and both sides of the fin; a second shallow trench isolation on the first shallow trench isolation; an interlayer dielectric layer on the second shallow trench isolation; a doped region in the bottom of the fin and the surface of the substrate; wherein, the top surface of the doping material layer levels with the bottom of the second shallow trench isolation.

In one aspect of the present invention, the distance from the top surface of the first shallow trench isolation to the top surface of the fin is 20˜60 nm, the thickness of the second shallow trench isolation is equal to or larger than half of the channel thickness.

In one aspect of the present invention, the doping material layer comprises borosilicate glass or phosphorosilicate glass. Specifically, the doping material layer comprises borosilicate glass for an N-type device while phosphorosilicate glass for a P-type device.

In one aspect of the present invention, the maximum doping concentration of the doped region is 1e18 cm⁻³˜1e19 cm⁻³.

There is provided a channel doping method for FinFET in the present invention, comprising: a borosilicate glass layer or phosphorosilicate glass layer is deposited after a fin formed on a substrate, then the dopants in the borosilicate glass or phosphorosilicate glass will diffuse into the channel region by anneal to form a expected heavily doped region. Comparing with the prior art, the punch through effect will be restrained and the complexity of process will be reduced at the same time in the present invention.

### BRIEF DESCRIPTION OF THE DRAWINGS

FIG. 1 and FIG. 7 are 3-D isometric drawings schematically illustrating some steps for fabricating the semiconductor Fin in accordance with the present disclosure.

FIGS. 2-6 are schematic views illustrating some steps for fabricating a semiconductor Fin in accordance with the present disclosure.

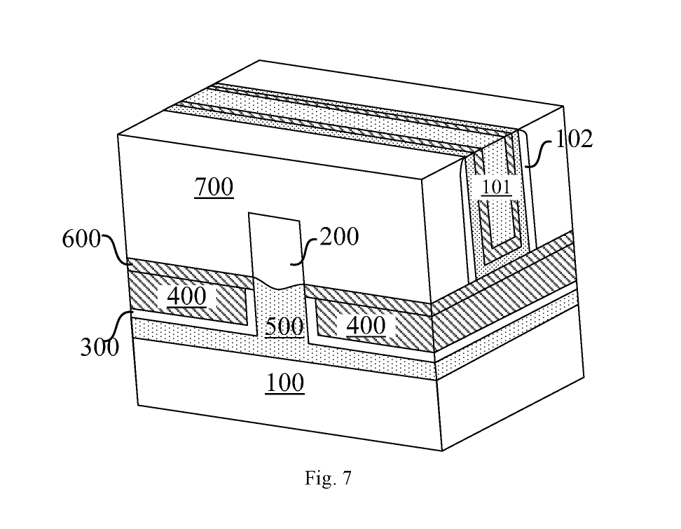

Referring to FIG. 7, there is provided a FinFET device in the present invention, comprising: a substrate 100; a fin 200 on the substrate 100; a gate stack on the middle portion of the fin; a first shallow trench isolation 400 on the substrate 100 and on both sides of the fin 200, wherein, the top of the first shallow trench isolation 400 is lower than the top of the fin; a doping material layer 300 between the first shallow trench isolation 400 and the substrate 100, wherein, the doping material layer 300 is extending along both of the fin 200 sides; a second shallow trench isolation 600 on the first shallow trench isolation 400; an interlayer dielectric layer 700 on the second shallow trench isolation 600; a doped region 500 in the bottom of the fin 200 and the surface of the substrate 100; wherein, the top surface of the doping material layer 300 levels with the bottom of the second shallow trench isolation 600.

In one embodiment of the present invention, the distance from the top surface of the first shallow trench isolation 400 and that of the fin 200 is 2060 nm, and the thickness of the second shallow trench isolation 600 is equal to half of the channel thickness.

In FinFET manufacturing, punch through effect always can be restrained by a heavily doped region in a portion of the fin under the channel region. In the prior art, a universal doping method is performed by an ion implantation to form the heavily doped region, however, it is hard to accurately control the ion implantation depth and avoid damages to the channel surface. Normally, a thin oxide film is formed on the channel surface to eliminate the damages, which may increase the complexity of the process. The present invention provides a doping material layer, dopants in which will diffuse to form a heavily doped region in the bottom of the fin. In the present invention, a heavily doped region with a uniform impurity distribution may be formed through only a few process steps, furthermore, there are some advantages of the present invention including, but not limited to, the following: damages to device surface can be diminished , channel punch-through effect can be restrained, and in the same time process complexity can be reduced.

The substrate 100 may comprise a silicon substrate (for example a silicon wafer). In one embodiment, the substrate 100 may comprise a variety of doping configuration. In other embodiments, the substrate 100 may include other basic semiconductor materials, for example, Ge or compound semiconductors, such as SiC, GaAs, InAs or InP. Specifically, the substrate 100 may have a thickness range of, but not limited to, 400 um-800 um.

The fin 200 is formed by etching the substrate 200, such that it has the same material and crystal orientation as the substrate 100. Normally, the fin 200 may have a length in a range of 80˜22 nm and a thickness in a range of 30˜50 nm. Source and drain regions are deposited in both ends of the fin 200 and have the same length. A channel region is in the middle of the fin 200 and just between the source region and drain region with a length in a range of 30˜50 nm.

There is provided a gate stack comprising a gate electrode stack 102 and a pair of insulating dielectric spacers 102 on both sides of the gate electrode stack 102. The gate electrode stack 102 may comprise a gate dielectric layer, a work-function tuning layer and a gate metal layer.

There is provided a phosphosilicate glass layer or a boronsilicate glass layer 300 on the substrate 100 and the fin 200, and the portion of which is adjacent to the fin 200 is of the same height with the top surface of the first shallow trench isolation 400.

The first shallow trench isolation 100 may be made of silicon dioxide or silicon nitride, and the top of the first shallow trench isolation 100 keeps the top of fin 200 at a distance of 20˜60 nm.

In on embodiment, the thickness of the second shallow trench isolation 600 is about half of the channel thickness, such that a vertical diffusion region can be covered when the dopants in the doping material layer 300 diffuse in the fin 200.

More details of the present invention may be described in the following with reference to the drawings. Each part of the drawings is not drawn to scale for purpose of clarity.

It could be understood that, while describing device structures, when a layer/element is recited as being “on” a further layer/element, the layer/element can be disposed directly on the further layer/element, or otherwise there may be an intervening layer/element interposed there between. Further, if a layer/element is “on” a further layer/element in an orientation, then the layer/element can be “under” the further layer/element when the orientation is turned.

To describe a situation such as directly on another layer, another area, “on . . . ” or “on . . . and adjacent to” is adopted in the specification.

Many particular details according to the present invention are described in the following, for example, device structure, material, dimension, operation process and technique, for purpose of clarity and comprehension. Those skilled in the art may understand the invention can be practiced by modifications and revisions not limited to the particular details. For example, a semiconductor material for the substrate and fin can be chosen from group IV semiconductors, such as Si or Ge, or groups III-V semiconductors, such as GaAs, InP, GaN, Si, or a stack of the foregoing semiconductor materials.

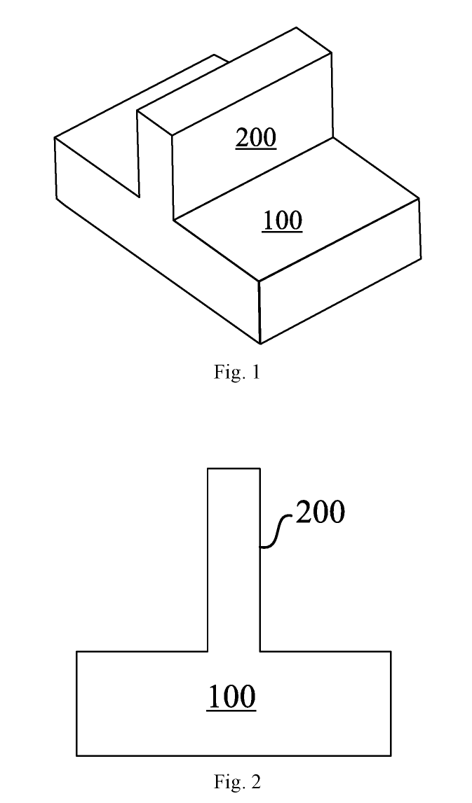

Referring to FIG. 1, a semiconductor fin 200 is formed on a substrate 100. For example, the substrate 100 and the fin 200 are formed of silicon. The fin 200 is formed by steps including, but not limited to, epitaxially growing a semiconductor layer on the substrate 100 and then etching the semiconductor layer to form the fin 200, the epitaxy method may be Molecular Beam Epitaxy (MBE) or other methods and the etching method may be dry etching or dry/wet etching. The fin 200 height ranges from 100 to 150 nm. FIG. 2 is a sectional view along a vertical direction of the semiconductor structure in FIG. 1.

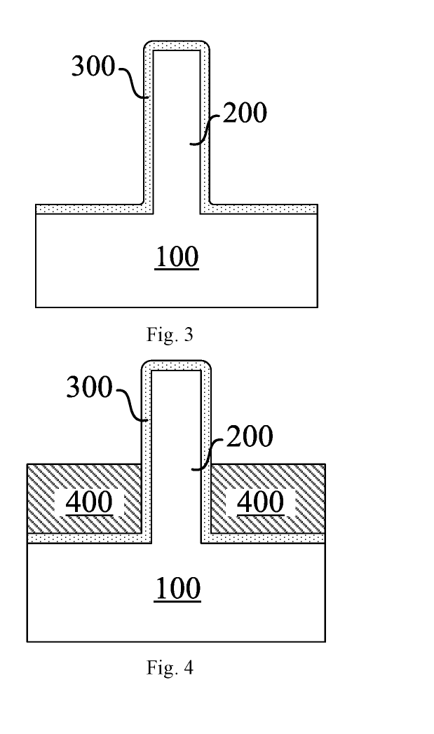

Referring to FIG. 3, after the fin 200 formed, a boronsilicate glass layer or a phosphorsilicate glass layer 300 is deposited on the semiconductor structure formed after the foregoing steps. Specifically, the boronsilicate glass layer or phosphorsilicate glass layer 300 may be formed by Chemical Vapor Deposition (CVD). The thickness of the boronsilicate glass layer or phosphorsilicate glass layer 300 can depend on the expected doping concentration in a region which is in the middle region of the fin along the fin length direction and just under the channel region.

Afterwards, the substrate 100 is isolated to form a first shallow trench isolation 400 with reference to FIG. 4. Preferably, a nitride silicon layer and a buffer oxide silicon pattern are formed on the fin 200 and the boronsilicate glass layer or phosphorsilicate glass layer 300 to form a mask for trench etching. Afterwards, a trench with a specific depth and spacer angle in the substrate 100 has been etched. Then, a thin silicon dioxide layer may be grown to smooth the trench corner angle and remove the damages on the silicon surface induced in the etching process. The trench will be filled with silicon dioxide after the oxidation. Then the semiconductor structure formed after the foregoing steps will be planarized through a CMP process with the silicon nitride layer as an etch-stop layer. Then, the semiconductor structure will be etched with the silicon nitride layer as a mask. To restrain a vertical diffusion in the fin 200 in later process, the etching depth is larger than an expected fin height, may be 20˜60 nm. The first shallow trench isolation 400 will be formed after the etching process, and the top of the first shallow trench isolation 400 keeps the top of fin 200 at a distance of 20˜60 nm. At last, the exposed silicon nitride layer will be removed by hot phosphoric acid to expose the fin 200 and the boronsilicate glass layer or the phosphosilicate glass layer 300.

Then, the boronsilicate glass layer or the phosphosilicate glass layer 300 will be isotropically etched and removed with the first shallow trench isolation 400 as a mask to expose the fin 200 above the first shallow trench isolation 400. Specifically, the etching method to remove the boronsilicate glass layer or the phosphosilicate glass layer 300 may be dry etching.

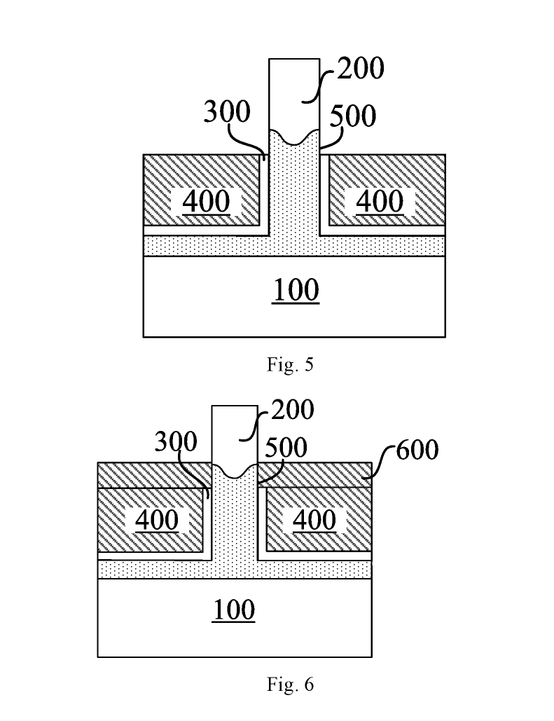

Then, referring to FIG. 5, an anneal process is performed to the semiconductor structure to drive the dopants in the boronsilicate glass layer or the phosphosilicate glass layer 300 diffusing into the substrate 100 and the fin 200 to form a doped region 500. A maximum concentration of the doped region 500 is 1e18 cm⁻³˜1e19 cm⁻³, which can effectively restrain source-drain punch through and prevent some carriers going into the channel region to influence threshold voltage of the device because of the over-high doping concentration. Because the dopants are diffusing isotropically in the anneal process, therefore, the top surface of the heavily doped region 500 is higher than that of the first shallow trench isolation 400 and the difference in height is half of the fin 200 width (Without considering the process error), that is just the diffusion length of the dopants in the boronsilicate glass layer or the phosphosilicate glass layer 300. The anneal temperature may be 800° C. in an embodiment.

Then, referring to FIG. 6, the semiconductor structure is isolated to form a second shallow trench isolation 600 to cover the doped region 500 that is formed above the first shallow trench isolation 400 by diffusion, such that carriers in the doped region 500 are preventing from going into the channel region and exerting a negative influence on device performance. Therefore, thickness of the second shallow trench isolation 600 is larger or equal to half of the fin 200 width, i.e., the diffusion length in the boronsilicate glass layer or the phosphosilicate glass layer 300. The thickness of the second shallow trench isolation 600 may be about 50%˜60% of the fin 200 width considering the possible process error in practice. The specific process steps to form the second shallow trench isolation 600 are the same as that to form the first shallow trench isolation 400 and will not be repeated here.

Then, a sacrificial gate stack is formed on the channel region and source/drain regions are formed next. The gate stack may be a single layer or a multiple layer. The gate stack may comprise polymer, amorphous silicon, poly silicon or TiN and the thickness may range from 10 to 100 nm. The gate stack may be formed by, but not limited to, the following method: thermal oxidation, chemical vapor deposition (CVD), atomic layer deposition (ALD), etc. The source/drain regions may be formed by, but not limited to, the following methods: ion implanting and annealing to activate ions later, situ doping and/or epitaxial growing.

Optionally, a spacer 102 are formed on sidewall of the gate stack to isolate the adjacent sacrificial gate stacks. The spacer 102 may formed by silicon nitride, silicon oxide, silicon oxynitride, silicon carbide and any combination thereof. The spacer 102 may comprise a multiple-layer. The spacer 102 may be formed by processes including depositing and etching, and the thickness ranges from 10 to 100 nm, for example, 30 nm, 50 nm or 80 nm.

Then, an interlayer dielectric layer 700 is deposited and planrized later to expose the sacrificial gate stack. Specifically, the interlayer dielectric layer 700 may be formed by CVD, high density plasma CVD, spin coating or other appropriate methods. The interlayer dielectric layer 105 may comprise SiO₂, carbon-doped SiO₂, BPSG, PSG, UGS, silicon oxynitride, low-k materials or any combination thereof. The interlayer dielectric layer 700 may have a thickness ranges from 40 to 150 nm, for example, 80 nm, 100 nm, or 120 nm. Then a planarization is performed to expose the gate stack to be flush with the interlayer dielectric layer 700 (the term “flush with” means, difference in height between the two is within a range of the semiconductor process error).

Then, the sacrificial gate stack is removed to form a sacrificial gate vacancy and expose the channel region. Specifically, the sacrificial gate stack may be removed by wet and/or dry etching. Plasma etching may be employed in a specific embodiment.

Then, referring to FIG. 1.7, there is formed a gate structure 101 in the sacrificial gate vacancy and the gate structure 101 comprises a gate dielectric layer, a work-function tuning layer and a gate electrode metal layer. Specifically, the gate dielectric layer may be thermal oxidation layer including silicon oxide, silicon oxynitride; or a high-k dielectric material, for example, selected from any one or combination from the group of HfAlON, HfSiAlON, HfTaAlON , HfTiAlON , HfON , HfSiON , HfTaON , HfTiON , Al2O3 , La2O3 , ZrO2 and LaAlO. The gate dielectric layer has a thickness ranges from 1 to 10 nm, for example, 3 nm, 5 nm or 8 nm. The work-function tuning layer may be formed by TiN, TaN, etc., and the thickness ranges from 3 to 15 nm. The gate electrode metal layer may comprise a single or a multiple layer and comprise material selected from any one or combination from the group of TaN, TaC, TiN, TaAlN, TiAlN, MoAlN, TaTbN, TaErN, TaYbN, TaSiN, HfSiN, MoSiN, RuTax and NiTax. The gate electrode metal layer has a thickness ranges from 10 to 40 nm, for example, 20 nm or 30 nm.

There is provided a channel doping method for FinFET in the present invention, comprising: a borosilicate glass layer or phosphorosilicate glass layer is deposited after a fin formed on a substrate, then the dopants in the borosilicate glass or phosphorosilicate glass will diffuse into the channel region by anneal to form a expected heavily doped region. Comparing with the prior art, the punch through effect will be restrained and the complexity of process will be reduced at the same time in the present invention.

Although the invention has been described with reference to the exemplary embodiments and advantages, it is understood that various changes and replacements and revisions may be made to the embodiments without departing the spirit and scope of the appended claims. For other exemplary embodiments, those skilled in the art may understand the order of the process steps can be changed within the present invention in its aspects.

Further, the present invention is not intend to limited to the particular details described in the specification, such as, technology, mechanism, fabrication, material composition, means, methods and steps. Those skilled in the art will recognize that for those elements already existing or to be developed, such as technology, mechanism, fabrication, material composition, means, methods or steps, if the elements used to be implement a specific function or result similar to the embodiments of the present invention, they can be employed according to the present invention. Therefore, those technology, mechanism, fabrication, material composition, means, methods and steps are in the scope of the appended claims.

1. A method of fabricating a FinFET device, comprising:
a. providing a substrate (100);
b. forming a fin (200) on the substrate (100);
c. depositing a doping material layer (300) on the semiconductor structure formed after the step b;
d. forming a first shallow trench isolation (400) on the semiconductor structure formed after the step c;
e. removing a portion of the doping material layer (300) which is not covered by the first shallow trench isolation (400);
f. performing an anneal process to form a doped region (500) in a channel region which is in the middle of the fin;
g. forming a second shallow trench isolation (600) on the semiconductor structure formed after the step f;
h. forming a source region and a drain region in both ends of the fin and forming a gate stack on the middle portion of the fin.

2. A method of claim 1, characterized in that, the distance from the top surface of the first shallow trench isolation (400) to the top surface of the fin (200) is 20˜60 nm.

3. A method of claim 1, characterized in that, the thickness of the second shallow trench isolation (600) is equal to or larger than half of the channel thickness.

4. A method of claim 1, characterized in that, the doping material layer (300) comprises borosilicate glass or phosphorosilicate glass.

5. A method of claim 1, characterized in that, the FinFET device is N-type and the doping material layer (300) comprises borosilicate glass.

6. A method of claim 1, characterized in that, the FinFET device is P-type and the doping material layer (300) comprises phosphorosilicate glass.

7. A method of claim 1, characterized in that, the maximum doping concentration of the doped region (500) is 1e18 cm⁻³˜1e19 cm⁻.

8. A FinFET device, comprising:
a substrate (100);
a fin (200) on the substrate (100);
a gate stack on the middle portion of the fin (200);
a first shallow trench isolation (400) on the substrate and both sides of the fin (200), wherein, the top of the first shallow trench isolation (400) is lower than the top of the fin (200);
a doping material layer (300) between the first shallow trench isolation (400) and the substrate (100), wherein, the doping material layer (300) is extending along both of the fin (200) sides;
a second shallow trench isolation (600) on the first shallow trench isolation (400);
an interlayer dielectric layer (700) on the second shallow trench isolation (600);
a doped region (500) in the bottom of the fin (200) and the top surface of the substrate (100);
wherein, the top surface of the doping material layer (300) levels with the bottom of the second shallow trench isolation (600).

9. A FinFET device of claim 8, characterized in that, the distance from the top surface of the first shallow trench isolation (400) and the top surface of the fin (200) is 20˜60 nm.

10. A FinFET device of claim 8, characterized in that, the thickness of the second shallow trench isolation (600) is larger or equal to half of the channel thickness.

11. A FinFET device of claim 8, characterized in that, the doping material layer (300) comprises boronsilicate glass or phosphosilicate glass.

12. A FinFET device of claim 8, characterized in that, the FinFET device is N-type and the doping material layer (300) comprises boronsilicate glass.

13. A FinFET device of claim 8, characterized in that, the FinFET device is P-type and the doping material layer (300) comprises phosphosilicate glass.

14. A FinFET device of claim 8, characterized in that, the maximum doping concentration of the doped region is 1e18 cm⁻³˜1e19 cm⁻³.
